(19) United States
(12) Patent Application Publication
(10) Pub. No.: US 2010/0139747 A1
(43) Pub. Date: Jun. 10, 2010

(54) Single-crystal nanowires and liquid junction solar cells

(75) Inventors: Xinjian Feng, State College, PA (US); Karthik Shankar, Edmonton (CA); Craig A. Grimes, Boalsburg, PA (US)

Correspondence Address: John A. Parrish;Law Offices of John A. Parrish, Suite 300, Two Bala Plaza, Bala Cynwyd, PA, 19004, US

(73) Assignee: The Penn State Research Foundation, University Park, PA (US)

(21) Appl. No.: 12/583,923

(22) Filed: Aug. 26, 2009

Related U.S. Application Data
(60) Provisional application No. 61/190,572, filed on Aug. 28, 2008.

(51) Int. Cl. H01L 31/0352; H01L 21/36; H01L 31/18

(52) U.S. Cl. 136/255; 438/104; 438/85; 977/762; 257/E21.461; 257/E31.004; 257/E31.032

(57) ABSTRACT

A method of making semiconducting oxide nanowire arrays on such as rutile is disclosed wherein a substrate is heated in the presence of a reaction mixture of non-polar solvent, semi-conductor metal oxide precursor source and strong acid to produce a nanowire array of a semiconducting oxide on the substrate. Dye sensitized solar cells that employ these nanowire arrays also are disclosed.

This application claims priority to U.S. Provisional Application 61/190,572 filed Aug. 28, 2008, the teachings of which are incorporated by reference by their entirety herein.

### STATEMENT OF GOVERNMENT INTERESTS

This invention was made with government support under grants DEFG02-06ER15772 and DEFG36-08601874 awarded by United States Department of Energy. The Government may have certain rights in the invention.

### FIELD OF THE INVENTION

The disclosed invention generally relates to solar cells and their method of manufacture, more particularly to dye sensitized solar cells.

### BACKGROUND OF THE INVENTION

Development of photoelectrochemical cells has generated strong interest in the use of TiO₂ in dye-sensitized solar cells (“DSSC”). A typical photoelectrochemical TiO₂ architecture employed in a DSSC includes a several micron-thick film formed of nanocrystalline TiO₂ nanoparticles on a transparent conducting oxide “TCO” glass substrate. The electron diffusion coefficient of these TiO₂ films, however, is several orders of magnitude less than that of single-crystal TiO₂.

Dye-sensitized solar cells that employ polycrystalline transparent films of arrays of TiO₂ nanotubes on a charge collecting TCO substrate also are known. Polycrystalline transparent films of arrays of TiO₂ nanotubes, however, are difficult to fabricate. Fabrication typically requires Ti film deposition, anodization, and then crystallization by thermal annealing. Thermal annealing, however, tends to reduce the conductivity of the TCO glass substrate on which the Ti films are deposited.

Various methods have been used to form oriented and disoriented TiO₂ nanorods or nanowires on non-transparent and/or non-conductive substrates. Methods that have been used include surfactant assisted self-assembly methods, templated sol-gel methods, high temperature chemical vapor deposition methods and high temperature vapor-liquid-solid growth methods. These methods, however, are unable to achieve aligned, densely packed polycrystalline nanowire arrays or single crystal nanowire arrays on TCO coated glass substrates.

Single-crystal, one-dimensional (“1-D”) semiconductor architectures are important in applications such as those that require large surface areas, morphological control and superior charge transport. Although considerable effort has focused on preparation of 1-D TiO₂, there are no known methods for growing 1-D single crystal or polycrystalline TiO₂ nanowire arrays directly onto TCO substrates such as SnO₂:F substrates. Lack of these methods greatly limits the performance of devices such as photoelectrochemical cells that employ 1-D TiO₂.

Modern excitonic solar cells typically harvest photons over the spectral range of about 350 nm to about 650 nm. The efficiency of these solar cells, however, is limited by poor quantum yields generated from red and near infrared photons.

Dye sensitized solar cells suffer various limitations. These limitations relate to functions such as poor charge transfer properties of dyes that absorb in the red and near-infrared regions of the solar spectrum.

Two methods have been explored to improve utilization of red and infrared photons by dye sensitized solar cells. A first method employs bis(bipyridine) and terpyridine ruthenium complexes with TiO₂ thin film in order to improve charge collection and enhance external quantum yields by absorbed red photons. A second method employs dyes that show superior absorption in the red and infrared regions of the solar spectrum, either in isolation or in admixture with existing Ru-based dyes. Neither of these methods, however, has achieved dye-sensitized solar cells that have acceptable performance.

A need therefore exists for new materials to achieve improved efficiencies in utilization of red and infrared photons and for devices that employ these materials.

### BRIEF DESCRIPTION OF THE DRAWINGS

FIGS. 1a and 1b are field-emission scanning electron microscope (FESEM; JEOL JSM-6300, Japan) top-surface images of the nanowire array grown on the SnO₂:F doped glass substrate of example 1;

FIG. 1c is a FESEM cross-sectional view of the sample shown in FIG. 1a;

FIG. 2a is an X-ray diffraction pattern of TiO₂ nanowires grown on the SnO₂:F doped glass substrate of example 1;

FIG. 2b is a high-resolution transmission electron microscope (HR-TEM; JEOL 2010F, Japan) image of the sample of FIG. 2a;

FIG. 2c is a selected-area electron diffraction pattern of the sample of FIG. 2a;

FIG. 3 shows photocurrent density and photoconversion efficiency versus potential of a rutile type, TiO₂ nanowire array electrode that employs 2.4 micron length TiO₂ nanowires produced according to example 5;

FIG. 4a shows J-V characteristics of the cell of example 1 under AM 1.5 illumination;

FIG. 4b shows J-V characteristics of the cell example 10 under AM 1.5 illumination.

FIG. 5 shows a schematic of a nanowire dye-sensitized solar cell.

FIG. 6a shows the molecular structure of Zinc 2,9,16,23-tetra-tert-butyl-29H, 31H-phthalocyanine exciton donor dye.

FIG. 6b shows absorption and emission spectra of ZnPc-TTB exciton donor dye and the absorption spectra of ruthenium polypyridine complex exciton acceptor dye.

FIG. 7 shows emission spectra of a 25 μM solution of ZnPc-TTB in THF under the following conditions: in the absence of acceptors (ZnPc-TTB), in the presence of 125 μM N-719 solution, and in the presence of 125 μM black dye solution

FIG. 8a shows a field emission scanning electron microscope cross section of rutile nanowires and (inset) top view of the rutile nanowire arrays;

FIG. 8b shows a high-resolution transmission electron microscope (HRTEM) image of the rutile nanowire of FIG. 8a.

FIG. 9a shows action spectrum of a liquid junction solar cell that includes N-719-coated rutile nanowires, with and without ZnPc-TTB exciton donor molecules in electrolyte.

FIG. 9b shows the effect of concentration of ZnPc-TTB exciton donor molecules on the external quantum yield of red photons in black dye sensitized nanowire solar cells.

FIG. 9c shows action spectrum of Ru-505-coated rutile nanowire solar cells, with and without ZnPc-TTB donor molecules in electrolyte.

### SUMMARY OF THE INVENTION

In a first aspect, the disclosed invention relates to a method of manufacture of semiconducting oxide nanowire arrays on a conducting oxide substrate. The method entails loading a conducting oxide substrate into a reactor in the presence of a reaction mixture of one or more non-polar solvents, one or more semi-conductor metal oxide precursor sources and one or more strong acids, and heating the reactor to produce a nanowire array of a semiconducting oxide on the substrate wherein the semiconducting oxide is selected from the group consisting of TiO₂, WO₃, CuO, ZnO, SnO₂, V₂O₅, NiO, Nb₂O₅, Ta₂O₅ and mixtures thereof. The substrate may be any of SnO₂:In coated glass substrates, SnO₂:In coated polyethylene, SnO₂:In coated polybutylene, SnO₂:In coated polyethyleneterephtalate, SnO₂:In coated copolymers of two or more of polyethylene, polybutylene, and polyethyleneterephtalate, SnO₂:F coated glass substrates, SnO₂:F coated polyethylene, SnO₂:F coated polybutylene, SnO₂:F coated polyethyleneterephtalate, SnO₂:F coated copolymers of two or more of polyethylene, polybutylene and polyethyleneterephtalate and mixtures thereof.

In a more particular aspect, the method entails immersing a SiO₂:F coated glass substrate into an aqueous Ti⁴⁺ precursor solution for about 2 to about 24 hours to yield a wetted substrate, drying the wetted substrate at about 400° C. to about 500° C. for about 0.5 hrs to about 4 hrs to yield a TiO₂ coated substrate, immersing the TiO₂ coated substrate into a reaction mixture that includes one or more nonpolar solvents, one or more Ti⁴⁺ sources and one or more strong acids, heating the reaction mixture at about 1° C./min to about 30° C./min to a reaction temperature of about 150° C. to about 250° C., holding at the reaction temperature for about 30 min to about 48 hours to produce a TiO₂ nanowire array on the TiO₂ coated substrate, immersing the TiO₂ coated substrate bearing the TiO₂ nanowires into a solution of a Group VB metal to produce wetted TiO₂ nanowires on the substrate, and drying the wetted nanowires at about 400° C. to about 500° C. for about 0.5 hr to about 4 hrs to yield TiO₂ nanowires having a coating thereon on the substrate.

In a second aspect, the disclosed invention relates to a method of manufacture of a dye sensitized, liquid junction solar cell. The method entails treating a substrate that bears an array of dense packed, preferably close packed, semiconductor nanowires, preferably rutile nanowires, with a solution of an exciton acceptor dye to produce an array of exciton acceptor dye coated semiconductor nanowires, infiltrating the array of acceptor dye coated semiconductor nanowires with a redox electrolyte that includes an exciton donor dye, attaching a counter-electrode to the array of coated semiconductor nanowires, wherein the exciton acceptor dye and the exciton donor dye have a Forster radius there between, and wherein spacings between the nanowires is about ±28% of the Forster radius.

In this first aspect, a low temperature process for preparing single-crystal and polycrystalline rutile type TiO₂ nanowire arrays that measure up to about 15 microns in length on conducting oxide substrate such as a TCO glass substrate such as a SnO₂:F coated glass substrate is disclosed. The crystalline TiO₂ nanowire arrays are grown by using a non-polar solvent/hydrophilic substrate interfacial reaction process under mild hydrothermal conditions.

The interfacial reaction process is performed at low temperatures up to about 150° C. and minimizes reductions in conductivity of the TCO glass substrate that typifies prior art methods. The low temperatures employed in the interfacial reaction process are compatible with polymeric substrates. The interfacial reaction process may be used to manufacture densely packed vertically oriented single crystal TiO₂, preferably close packed, vertically oriented single crystal TiO₂ directly onto TCO substrates along the (110) rutile crystal plane with a preferred (001) orientation. The interfacial reaction process also may be used to prepare crystalline anatase type TiO₂ nanowire arrays. The interfacial reaction process, moreover, may be employed to synthesize nanowires of other semiconductor metal oxides such as, but not limited to WO₃, CuO, ZnO, SnO₂, V₂O₅, NiO, Nb₂O₅, Ta₂O₅, as well as other metal oxides such as Fe₂O₃ and mixtures thereof. The nanowires may be in single-crystal form as well as in polycrystalline nanowire array form.

The nanowires of TiO₂ and other semiconductor metal oxides such as, but not limited to WO₃, CuO, ZnO, SnO₂, V₂O₅, NiO, Nb₂O₅, Ta₂O₅, as well as other metal oxides such as Fe₂O₃ and mixtures thereof may be coated with a Group VB metal such as Nb, V, Ha, Ta, other metals such as Fe and mixtures thereof, alloys thereof as well as oxides of the corresponding metals and mixtures of those oxides. Substrates that employ semiconductor oxide nanowire arrays such as TiO₂ nanowire arrays may be used in a wide variety of devices such as sensors and solar cells to yield improved photoconversion efficiency.

In this second aspect, the invention relates to liquid junction solar cells that employ substrates that have densely packed arrays of nanowires of semiconductor metal oxides bear exciton acceptor molecules thereon and an electrolyte dispersed between the nanowires. Semiconductor oxides include but not limited to TiO₂, WO₃, CuO, ZnO, SnO₂, V₂O₅, NiO, Nb₂O₅, Ta₂O₅, as well as other metal oxides such as Fe₂O₃ and mixtures thereof, preferably TiO₂. Preferably, the substrates are TCO substrates and the densely packed arrays of TiO₂ nanowires are close packed arrays of single crystal rutile type TiO₂. Also, and preferably, the nanowires are vertically oriented to the substrate.

The electrolyte includes one or more exciton donor dyes that generate excitons when exposed to sunlight. The spacing between adjacent nanowires in the densely packed array is within the range of about ±28% of the Forester radius for exciton donor molecules in the exciton donor dye and the exciton acceptor molecules on the nanowires so that excitons generated by the dye are readily transferred to the exciton acceptor molecules on the nanowires. The electrolyte preferably is a redox electrolyte that includes a luminescent dopant.

The dye-sensitized solar cells wherein high surface area nanowire arrays are employed in combination with exciton donor chromophores possessing high fluorescence quantum yields generate high external quantum efficiencies (E.Q.E.) for red photons. The dye-sensitized solar cells achieve several advantages over conventional dye-sensitized solar cells. These advantages include but are not limited to a spectral response that matches the AM 1.5 solar spectrum to within about 50% to about 65%, and an increase in the Quantum yield for red photons at about 675 nm to about 680 nm by a factor of 4 for N-719 dye and by a factor of 1.5 for black dye.

### DETAILED DESCRIPTION OF THE INVENTION

### Definitions

As used herein, the following terms are understood to mean: “red photons” mean photons that have a wavelength of about 620 nm to about 740 nm; “near infra-red photons” mean photons that have a wavelength of about 740 nm to about 1500 nm; vertically oriented nanowires mean nanowires that are oriented at 85 deg±5 deg to a substrate and close packed nanowire arrays mean nanowire arrays that have a packing density of about 2×10¹⁰ nanowires to about 9×10¹⁰ nanowires per mm².

### Materials

Exciton donor dyes and exciton acceptor dyes are chosen on the basis of spectral overlap in the range of about 675 nm to about 700 nm between donor dye molecules and acceptor dye molecules. Typical combinations of donor dyes and acceptor dyes have an overlap in the spectral range of about 675 nm to about 700 nm. Combinations of donor dyes and acceptor dyes are chosen to maximize the extent of overlap in the spectral range of about 675 nm to about 700 nm. Typically, this extent of overlap is about 30% to about 100%, preferably about 65% to about 100%, more preferably about 80% to about 100% in the spectral range of about 675 nm to about 700 nm. Examples of exciton donor dyes include but are not limited to N,N-di(2,6-diisopropylphenyl)-1,6,7,12-tetra(4-tert-butylphenyoxy)-perylene-3,4,9,10-tetracarboxylic diimide; Tris-(8-hydroxyquinoline) aluminum and mixtures thereof.

Exciton acceptor dye types that may be employed to coat nanowires such as TiO₂ nanowires with exciton acceptor molecules include but are not limited to ruthenium based dyes that have an absorption spectrum of about 400 nm to about 750 nm; Ru(4,4′-dicarboxylic acid-2,2′-bipyridine)(4,4′-dinonyl-2,2′-bipyridine)(NCS)₂: NaRu(4-carboxylic acid-4′-carboxylate)(4,4′-bis[(triethyleneglycolmethylether)-heptylether]-2,2′-bipyridine)(NCS)₂.

Other exciton acceptor dyes that may be employed to coat nanowires such as TiO₂ nanowires include but are not limited to black dye such as that available from Solaronix, organic dyes, IR dyes and mixtures thereof. Organic dyes may include but are not limited to thiophenes, indolines, squaraines, linear acenes, fluorenes and mixtures thereof. IR dyes may include but are not limited to croconines, cyanines, porphyrins & phthalocyanines, tris & tetrakis amminium, Dithiolene Nickel, Dithiolene-Noble metal, Squaraines, Anthraquinones and mixtures thereof. Examples of organic dyes that may be employed include but are not limited to 3-{5-[N,N-bis-(9,9-dimethylfluorene-2-yl)phenyl]-thiophene-2-yl}-2-cyanoacrylic acid: 3-{5-[N,N-bis(9,9-dimethylfluorene-2-yl)phenyl]-2,2-bisthiophene-5-yl}-2-cyano-acrylic acid: 3-{5-[N,N-Bis(9,9-dimethylfluorene-2-yl)phenyl]-3,4-(ethylenedioxy)thiophene-2-yl}-2-cyanoacrylic acid: 3-{5′-[N,N-Bis(9,9-dimethylfluorene-2-yl)phenyl]-2,2′-bis(3,4-ethylenedioxythiophene)-5-yl}-2-cyanoacrylic acid and mixtures thereof. Examples of IR dyes include but are not limited to 9(10),16(17),23(24)-tri-tert-butyl-2-carboxy-5, 28:14, 19-diimino-7, 12:21,26 dinitrilotetrabenzo[c,h,m,r]tetraazacycloeicosinator-(22)-N29,N30,N31,N32 zinc (II). Examples of ruthenium based dyes that may be employed have the general formula RuL2(NCS)2:2 TBA. Examples of ruthenium based dyes that may be employed include but are not limited to RuL2(NCS)2:2 TBA (N-719 from Solaronix, Switzerland), Ru-505 from Solaronix, Z-907 from Solaronix, Switzerland, Ru-bipyridylphosphonic acid complexes and mixtures thereof. Ru-505 is similar to N-719. However, absorption of Ru-505 extends to about 650 nm instead of to about 750 nm for N-719 and instead of to about 920 nm for black dye.

Mixtures of black dye and ruthenium based dyes may also be employed. These mixtures may include about 1% to about 99% by weight black dye, remainder ruthenium based dye.

### Synthesis of TiO2 Nanowire Arrays.

Generally, dense packed crystalline nanowire arrays, preferably close packed arrays such as semiconductor oxide nanowire arrays such as TiO₂ nanowire arrays are grown directly onto a substrate. The nanowires such as single crystal, rutile type nanowires typically have a length of up to about 15 microns and a diameter of about 15 nm to about 35 nm. In forming the arrays, a substrate is loaded into a sealed reactor in the presence of a reaction mixture of one or more non-polar solvents, one or more semiconductor metal oxide precursor sources, preferably Ti⁴⁺ sources, and one or more strong acids. The reactor then is heated to a reaction temperature sufficient to generate semiconductor oxide nanowire arrays directly onto the substrate.

Where the semiconductor oxide is TiO₂, one or more of single crystal rutile type TiO₂ nanowire arrays, polycrystalline rutile type TiO₂ nanowire arrays, single crystal anatase TiO₂ nanowire arrays as well as polycrystalline, anatase type TiO₂ nanowire arrays may be grown directly onto a substrate. Where it is desired to produce one or more of rutile type nanowires as well as anatase type nanowires, substrates which may be used include but are not limited to SnO₂:In (ITO) coated glass substrates such as those available from Delta Technologies, LTD; SnO₂:F (FTO) coated glass substrates such as those available from Delta Technologies, LTD. Other substrates that may be employed include but are not limited to ITO coated polymeric substrates such as olefins such as polyethylene, polybutylene, and polyethyleneterephtalate (PET), and other polymers such as PTFE as well as copolymers thereof. FTO coated polymeric substrates such as olefins such as polyethylene, polybutylene, and polyethyleneterephtalate (PET), and other polymers such as PTFE as well as copolymers thereof; FTO coated polymeric substrates, such as polyamides such as Kapton from DuPont Corp, can be prepared by depositing FTO nanoparticles onto a polymer substrate or by sputtering FTO onto a polymer.

Where it is desired to produce rutile type TiO₂ nanowire arrays, the reaction mixture may include one or more non-polar solvents in an amount of about 50% to about 98%, preferably about 90% to about 98%, more preferably about 95% to about 98%, one or more Ti⁴⁺ sources in an amount of about 1% to about 25% preferably about 1% to about 10% more preferably about 1% to about 5% and one or more strong acids in an amount of about 1% to about 25%, preferably about 1% to about 10% more preferably about 1% to about 5% where all amounts of non-polar solvents, Ti⁴⁺ sources and strong acids where all amounts of solvent, Ti⁴⁺ source and acid are based on the total volume of the reaction mixture. Non-polar solvents that may be employed in the reaction mixture employed to produce rutile type nanowire arrays include but are not limited to toluene, benzene, cyclohexane, oleic acid, hexane and mixtures thereof, preferably toluene. Ti⁴⁺ sources that may be employed in the reaction mixture include but are not limited to titanium tetrachloride, tetrabutyl titanate, isopropyl titanate, titanium trichloride and mixtures thereof. Strong acids that may be employed in the reaction mixture include but are not limited to hydrochloric acid, sulfuric acid, phosphoric acid, nitric acid and mixtures thereof.

When forming rutile type TiO₂ nanowires, a sealed reactor is heated at about 1° C./min to about 30° C./min, preferably at about 10° C./min to about 30° C./min, more preferably at about 10° C./min to about 15° C./min to a reaction temperature of about 150° C. to about 250° C., preferably about 160° C. to about 180° C., more preferably about 170° C. to about 180° C. The reactor is held at the reaction temperature for about 30 min to about 48 hours, preferably about 4 hrs to about 20 hrs, more preferably about 10 hrs to about 20 hrs to produce a layer of single crystal, rutile type TiO₂ nanowires on the substrate.

In another aspect, semiconductor oxide nanowires such as TiO₂ nanowires such as rutile type-TiO₂ nanowires may be coated with one or more Group VB metals or one or more oxides of a Group VB metal such as Nb, V, Ha, Ta, mixtures thereof as well as alloys thereof. The thickness of each of the metal coating and metal oxide coating may vary from about 0.25 nm to about 10 nm, preferably about 0.25 nm to about 5 nm, more preferably about 0.25 nm to about 1 nm.

In manufacture of metal-coated nanowires, a substrate is immersed into a solution of a precursor for a semiconductor oxide to yield a wetted substrate. The wetted substrate then is dried and loaded into a sealed reactor that includes a reaction blend of the semiconductor oxide precursor. The reactor then is heated to grow oxide nanowires on the substrate. The nanowires then are treated with a solution of a metal or metal oxide or mixture thereof, such as a Group VB metal or metal oxide to produce wetted nanowires. The wetted nanowires than are dried to yield coated, semiconductor oxide nanowires such as any of metal coated, semiconductor oxide nanowires and metal oxide coated, semiconductor oxide nanowires.

To further illustrate, where metal coated TiO₂ nanowires are desired, a substrate such as a SiO₂:F coated glass substrate is cleaned and then immersed in an aqueous Ti⁴⁺ precursor solution such as TiCl₄ for about 2 hr to about 24 hours to yield a wetted substrate. The wetted substrate then is dried in air at about 400° C. to about 500° C. to yield a substrate that bears a TiO₂ film of about 10 nm to 20 nm thickness. The wetted substrate is loaded into a sealed reactor that includes a reaction blend of one or more non-polar solvents, one or more Ti⁴⁺ sources, and one or more strong acids.

The reactor then is heated at about 1° C./min to about 3° C./min for a time sufficient to grow TiO₂ nanowire arrays. The arrays are washed in a lower alkanol such as ethanol and dried. The non-polar solvents may be present in the reaction blend in an amount of about 75% to about 98%, the Ti⁴⁺ sources may be present in reaction blend in an amount of about 1% to about 15%, and the strong acids may be present in the reaction blend in an amount of about 1% to about 10% where all amounts of non-polar solvents, Ti⁴⁺ sources and strong acids are based on the total weight of the reaction mixture

The substrate, such as a TCO substrate that bears the TiO₂ nanowires may be immersed into a solution of a metal such as a metal of one or more of Groups V of the periodic table, preferably Group VB, to yield wetted TiO₂ nanowires. Where Group VB metals are employed, metals that may be employed include Nb, V, Ha, Ta or alloys thereof, preferably Nb.

Solvents that may be used to form solutions of the Group VB metals include but are not limited to lower alkanols such as ethanol, acetone, isopropanol or mixtures thereof, preferably ethanol.

Where Group VB metals are employed, the wetted TiO₂ may be dried in air at about 400° C. to about 500° C. for about 0.5 hr to about 4 hrs to yield Group VB metal coated TiO₂ nanowires on the TiO₂ coated substrate. Where Group VB metals are employed, the thickness of the coating of the Group VB metal or Group VB metal oxide may vary from about 1 nm to about 20 nm, preferably about 1 nm to about 2 nm.

### Dye Sensitization and Liquid Junction Solar Cell Construction.

During manufacture of liquid junction solar cells, a substrate such as an FTO coated substrate that bears dense packed semiconductor oxide, preferably close packed TiO₂ nanowire arrays, is treated with a solution of an exciton acceptor dye to sensitize the nanowires.

A liquid junction solar cell may be prepared by infiltrating a solution of an exciton acceptor dye into the sensitized, dense packed nanowires, preferably sensitized, closed packed TiO₂ nanowire arrays with a redox electrolyte such as MPN-100 (Solaronix, Inc., Switzerland). MPN-100 contains 100 mM of tri-iodide in methoxypropionitrile and is modified to contain an exciton donor dye possessing excellent luminescence properties including but not limited to phthalocyanines, porphyrins, fluorenes, thiophenes, fluoresceins, linear acenes, coumarins, cyanines, oxazines, squaraines and xanthenes. An example of dye is ZnPc-TTB. A glass slide may be sputter-coated with 100 nm of Pt to serve as a counter-electrode.

Electrode spacing between the dye coated TiO₂ nanowire electrode and the Pt counter-electrode may be provided with a 25-micron thick SX-1170 spacer (Solaronix Inc., Switzerland). The spacer includes a central window to define the active area of the cell. Comparison cells are made as above except that an exciton donor dye is not included in the redox electrolyte.

Solutions of acceptor dyes that may be used include an exciton acceptor dye in a solvent blend of a lower alkanol and an aprotic solvent. Acceptor dyes that may be used include ruthenium polypyridinium dyes and black dye. Where black dye is employed, deoxycholic acid is included in the solution to minimize formation of agglomerates of black dye on the nanowires. Typically, deoxycholic acid is employed in amounts of about 1% to about 10%. Lower alkanols that may be employed in the solvent blend include but are not limited to ethanol and other lower alkanols such as methanol. Aprotic solvents that may be employed in the solvent blend include acetonitrile and others such as THF. The lower alkanols and aprotic solvents in the blend may be used in volume ratios of about 15 to about 1. The concentration of acceptor dye in the solvent blend may vary from about 3×10⁻⁴M to about 3×10⁻³M.

The sensitized nanowires are immersed in an electrolyte solution that includes a redox electrolyte for about 10 min to about 3600 min. to disperse the electrolyte and donor dye within spacings between the nanowires. The redox electrolyte includes an exciton donor dye. The concentration of the donor dye in the electrolyte may vary from about 3×10⁻⁴ M to about 3×10⁻¹M, preferably about 1×10⁻³M to about 1×10⁻¹M, more preferably about 1×10⁻²M to about 5×10⁻²M.

In the liquid junction solar cells, an electrolyte that includes an exciton donor dye is maintained within the spacings between the nanowires. The width of these spacings, as defined by the packing density of the nanowires, is about ±28% of the Foerster radius between the donor molecules of the dye in the electrolyte and the acceptor molecules on the nanowires, preferably about equal to the Foerster radius. The Forster radius Ro for a specific donor molecule-acceptor molecule combination may be determined from the well known expression

$$Ro = i = \frac{9000 ln ( 10 ) {κ}^{2} \cdot {Φ}_{D}}{128 {π}^{5} {N}_{A} {n}^{4}} [ {\int }_{0}^{∞} {F}_{D} ( v ) {ɛ}_{A} ( v ) {v}^{- 4} d v ]$$

where the refractive index is given by n; N_{A} is the Avogadro number, κ is the dipole orientation factor, and Φ_{D} is the donor fluorescence quantum yield in the absence of acceptor. The terms within the square brackets constitute the spectral overlap integral J of the donor fluorescence intensity (normalized to unit area) and the absorption spectrum of the acceptor. Rₒ for various exciton donor molecule-acceptor molecule combinations is shown in Table 1:

TABLE I

| Exciton donor Dye | Exciton acceptor Dye | Rₒ | |
|---|---|---|---|
| Ru-505 | ZnPc-TTB | 0.98 | nm |
| N-719 | ZnPc-TTB | 3.2 | |
| Black Dye | ZnPc-TTB | 4.1 | |

Close-packed arrays of TiO₂ nanowires have a packing density of about 2×10¹⁰ nanowires/mm² to about 9×10¹⁰ nanowires/mm². Spacings between adjacent nanowires in the closed packed arrays of nanowires thus may vary from about 2 nm to about 10 nm,

### Morphological and Optical Characterization of Liquid Junction Solar Cells

Optical absorption, and photoluminescence of samples are characterized with FESEM (JEOL 6700F), HRTEM (Phillips 420 T), UV-vis-NIR spectrophotometer (Perkin-Elmer (λ-950) and fluorescence spectrophotometer (Photon Technology Instruments), respectively.

### Electrical Measurements of Nanowire Arrays of Liquid Junction Solar Cells

For collection of device action spectra, illumination is provided by a 300 W Oriel Solar Simulator from USA. An Oriel Cornerstone 130 monochromator is used for collection of action spectrum, and the intensity is calibrated using a Newport-Oriel photodetector (single crystalline silicon) and power meter. For longer wavelengths (+650 nm), a band-stop optical filter with a 550 nm cutoff is used

The invention is further described below by reference to the following non-limiting examples:

### Example 1

A SnO₂:F coated glass substrate (TEC-8, 8 ohm per square cm from Hartford Glass Co. Inc. USA) is employed. The substrate is cleaned by sonication at 20° C. sequentially in acetone, 2-propanol, and methanol, rinsed with deionized water, and then dried in flowing nitrogen at 20° C.

The resulting, clean SnO₂:F coated glass substrate is loaded into a sealed, 23 cc Teflon reactor from Parr Instrument Co. USA. The reactor is filled with 10 ml toluene, 1 ml tetrabutyl titanate, 1 ml titanium tetrachloride (1 M in toluene) and 1 ml hydrochloric acid (37 wt %). The reactor is heated at 5° C./min to 30° C. and held at 180° C. for 2 hrs to produce arrays of single crystal, rutile type TiO₂ nanowires that measure 2.1 microns long and 20 nm wide on the substrate. The rutile nanowires grow along the (110) crystal plane with a preferred (001) orientation.

The TiO₂ arrays then are washed with ethanol and dried in air at 180° C.

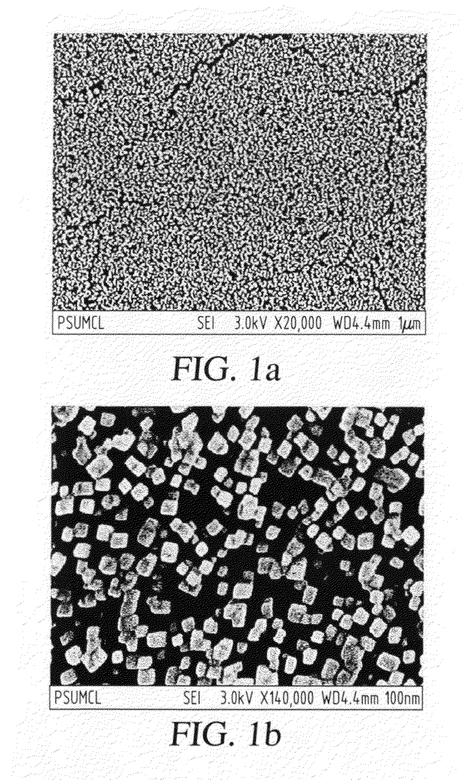

FESEM images of the arrays are shown in FIGS. 1a, 1b.

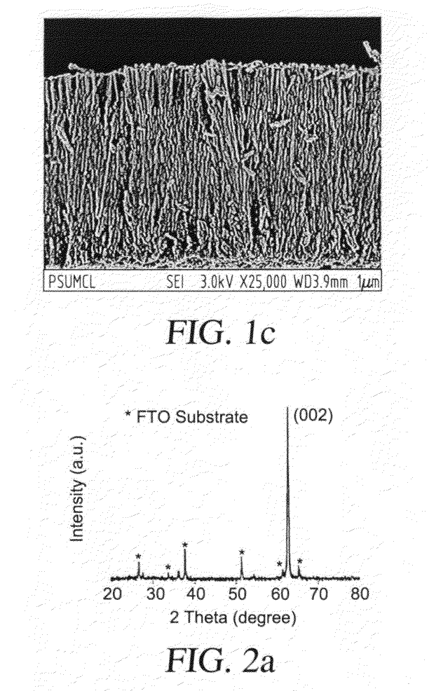

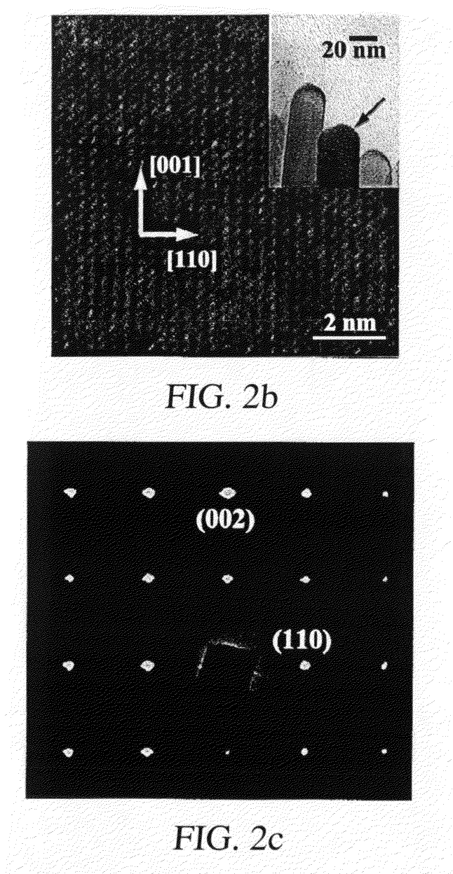

These images reveal that the nanowires have a packing density of about 10¹³ nanowires per square centimeter. The nanowires also are highly uniform and have flat tetragonal crystallographic planes. The FESEM image in FIG. 1c shows that the nanowires are vertically oriented to the SnO₂:F coated glass substrate. FIG. 2a shows an X-ray diffraction pattern (XRD; Scintag Inc., CA. USA) of the nanowires of Example 1.

The diffraction pattern shows that the nanowires are rutile (JCPDS file no. 21-1276). The enhanced (002) peak in the pattern confirms that rutile is well crystallized and is perpendicular to the substrate. The TEM image of FIG. 2b and the electron diffraction pattern of FIG. 2c confirm that the nanowires are single crystal. The TEM image of FIG. 2b also confirms a (110) inter-plane distance of 0.325 nm.

### Example 2

The process of example 1 is employed except that the reaction is performed for 4 hrs to produce single crystal, rutile type TiO₂ nanowires that measure 3.2 micron in length and a width of 22 nm.

### Example 3

The process of example 1 is employed except that the reaction is performed for 8 hrs to produce single crystal, rutile type TiO₂ nanowires that measure 3.8 micron in length and a width of 24 nm.

### Example 4

The process of example 1 is employed except that the reaction is performed for 22 hrs to produce single crystal, rutile type TiO₂ nanowires that measure 4 micron in length and a width of 25 nm.

### Example 5

The process of example 1 is employed except that the reaction is performed for 30 hrs to produce single crystal, rutile type TiO₂ nanowires that measure 2.4 micron in length and a width of 20 nm. A sample size of 0.5 cm² of the nanowires is immersed into 1 M KOH electrolyte under 1.5 AM solar illumination (100 mW/cm²) Spectra Physics Simulator, USA) for use as an electrode.

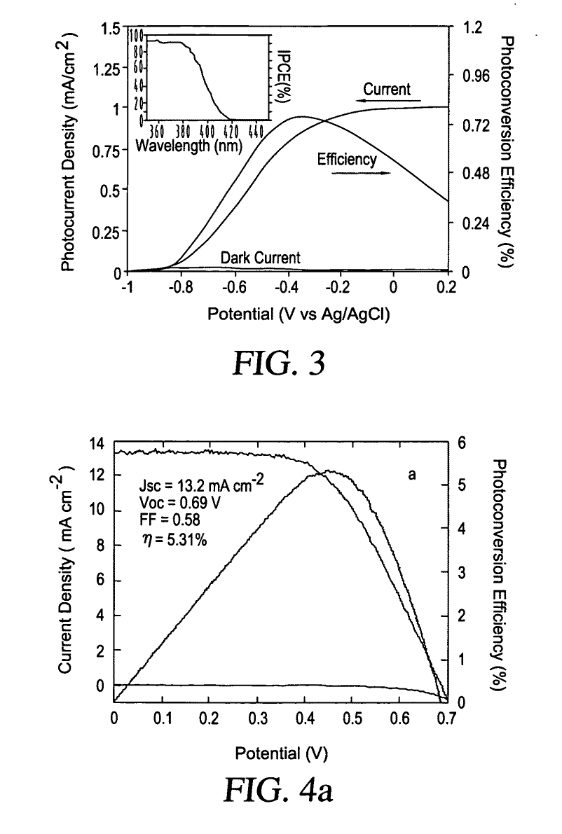

The potential of the sample is scanned at a rate of 20 m V/s. The results are shown in FIG. 3. The inset of FIG. 3 shows the photon-to electron conversion efficiency (IPCE) as a function of wavelength for the TiO₂ nanowire photoelectrode without bias. The IPCE values reach a maximum of 90% at 380 nm.

### Example 6

The process of example 1 is employed except that the reaction is performed for 48 hrs to produce single crystal, rutile type TiO₂ nanowires that measure 2.0 micron in length and width of 20 nm.

### Example 7

### Nb₂O₅Coated TiO₂ Nanowires

The SnO₂:F substrate cleaned as in example 1 is immersed into a 0.1 M TiCl₄ aqueous solution for 8 hrs and then heated in air at 500° C. for 0.5 hrs to generate a substrate that bears a 20 nm thick layer of TiO₂ over the SnO₂:F coating on the substrate. The coated substrate then is processed as in example 6 to generate TiO₂ nanowires on the TiO₂ layer on the SnO₂:F glass substrate. The substrate bearing the TiO₂ nanowires then is dipped into a 5 mM NbCl₅ dry ethanol solution for 1 min and heated in air at 500° C. for 0.5 hrs to generate Nb₂O₅ coated TiO₂ nanowires. The thickness of the Nb₂O₅ coating is 1 nm.

### Example 8

The procedure of example 7 is employed except that the SnO₂:F substrate cleaned as in example 1 is immersed into a 0.1 M TiCl₄ solution for 8 hrs and then heated in air at 500° C. for 1 hr to generate a coated substrate that bears a 10 nm thick layer of TiO₂.

Photoelectrochemical characterization of the nanowire arrays is performed using a three-electrode configuration (Keithley 2400 source-meter and a CHI 600B potentiostat), with TiO₂ nanowires on SnO₂:F glass as the working photoelectrode, saturated Ag/AgCl as the reference electrode, and platinum foil as the counter electrode.

The light-to-chemical energy conversion efficiency of the nanowires is determined in the two-electrode configuration with TiO₂ nanowires on SnO₂:F glass substrate as the working photoelectrode and platinum foil as a counter electrode. The nanowires show a photoconversion efficiency of about 0.75%. The electron mobility of single crystal rutile is 1 cm²V⁻¹s⁻¹. This is over two orders of magnitude higher than for nanoparticulate TiO₂ films.

Unlike nanoparticle-based electrodes that require a positive bias of about 0.5 V to 1 V (vs. reference electrode) to completely separate the light generated electron-hole pairs, the photocurrent of the TiO₂ nanowire array-based electrode of the invention increases sharply to saturation at −0.25 V, indicative of both low series resistance and facile separation of photogenerated charges.

### Manufacture of Liquid Junction Solar Cells

### Example 9

A SnO₂:F substrate bearing arrays of 2 micron long, 20 nm wide TiO₂ nanowire arrays produced as in example 6 are immersed overnight in a 0.5 mM solution of commercially available N719 dye of the formula C₅₈H₈₆O₈N₈S₂Ru (Solaronix Inc., Switzerland) to produce a dye coated TiO₂ electrode.

A liquid junction solar cell is prepared by infiltrating the dye coated TiO₂ electrode with commercially available redox electrolyte MPN-100 (Solaronix, Inc., Switzerland) that contains 100 mM of tri-iodide in methoxypropionitrile. A glass slide is sputter-coated with 100 nm of Pt to serve as a counter-electrode. Electrode spacing between the dye coated TiO₂ electrode and the Pt counter-electrode is provided with a 25-micron thick SX-1170 spacer (Solaronix Inc., Switzerland).

Photocurrent density and photovoltage of the cell is measured with active sample areas of 0.4 cm²-0.5 cm² using AM-1.5 simulated sunlight produced by a 500 W Oriel Solar Simulator from Startford Conn. USA

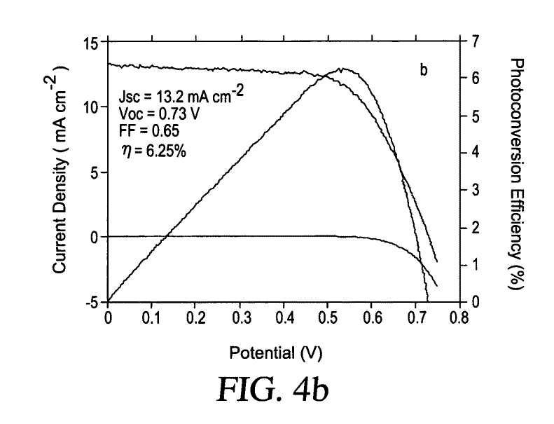

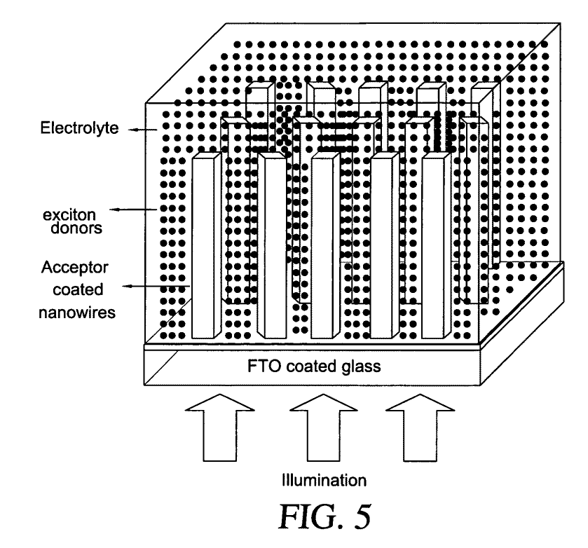

FIG. 4a shows the J-V characteristics of the cell under AM 1.5 illumination with active sample areas of 0.4 cm²-0.5 cm². An overall photoconversion efficiency of 5.31% is achieved with an open circuit voltage (V_{oc}) of 0.69 V, a short circuit current density (J_{sc}) of 13.2 mA cm⁻², and a fill factor (FF) of 0.58 and an active sample area of 0.44 cm².

### Example 10

The procedure of example 9 is used except that the SnO₂:F substrate that bears arrays of Nb₂O₅ coated TiO₂ nanowires of Example 7 is employed to produce a cell.

FIG. 4b shows the J-V characteristics of the cell.

An overall photoconversion efficiency of 6.25% is achieved under AM 1.5 illumination, with an open circuit voltage (V_{oc}) of 0.73 V, short circuit current density (J_{sc}) of 13.2 mA cm⁻², and fill factor (FF) of 0.65 and an active area of 0.41 cm².

### Example 11

### Manufacture of Liquid Junction Solar Cell

A FTO coated glass substrate (TEC 8, 8 ohm/cm2) from Hartford Glass Co, USA that bears close packed TiO₂ nanowire arrays is laminated to a 25 micron thick SX-1170 spacer (Solaronix Inc., Switzerland) that includes a central window that forms the active area of the device. The active area is measured using a calibrated optical microscope and is 0.20 cm².

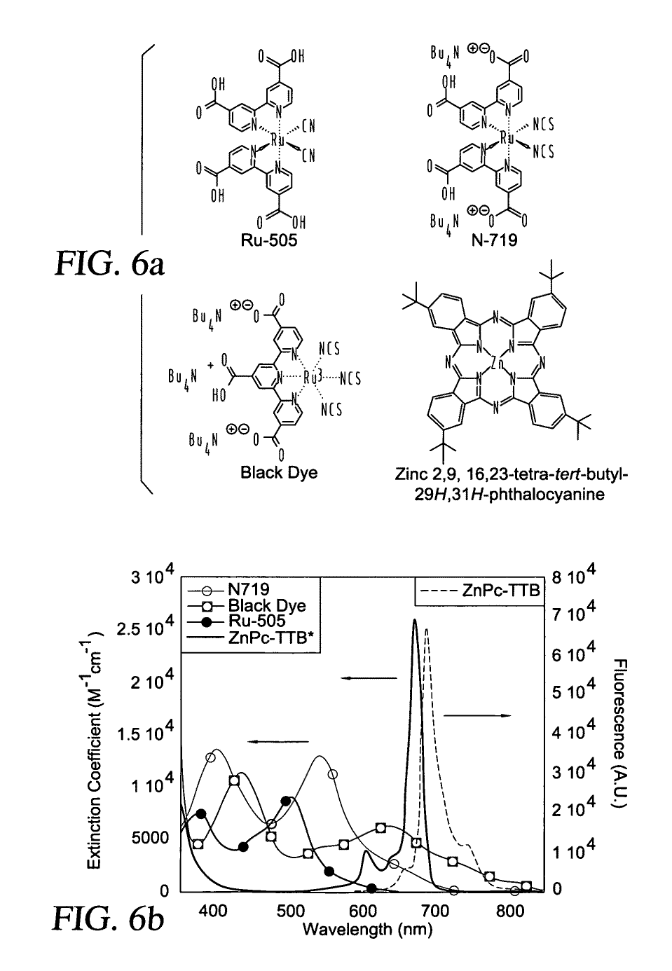

The TiO₂ nanowire arrays are sensitized by RU-505 ruthenium polypyridinium dye by overnight immersion in a 1:1 solution of the dye in a blend of ethanol and acetonitrile of concentration 5×10⁻⁴M at room temperature. The sensitized TiO₂ nanowires then are immersed into an electrolyte solution that includes a redox electrolyte and ZnPc-TTB donor dye of the formula shown in FIG. 6a. The redox electrolyte contains lithium iodide (LiI, 0.1 M), diiodine (I2, 0.02 M), 4-tertbutylpyridine (TBP, 0.5 M), butyl methyl imidazolium iodide (BMII, 0.6 M), and guanidinium thiocyanate (GuNCS, 0.1 M) in a mixture of acetonitrile, tetrahydrofuran, and methoxypropionitrile (v/v/v 4/5/1). The ZnPc-TTB is present in the redox electrolyte in an amount of about 1 mg/ml.

### Example 11A

The procedure of example 11 is followed except that the ZnPc-TTB is present in the redox electrolyte in an amount of about 1.5 mg/ml.

### Example 11B

The procedure of example 11 is followed except that the ZnPc-TTB is present in the redox electrolyte in an amount of about 2.0 mg/ml.

### Example 11C

The procedure of example 11 is followed except that the ZnPc-TTB is present in the redox electrolyte in an amount of about 3 mg/ml.

### Example 11D

The procedure of example 11 is followed except that the ZnPc-TTB is present in the redox electrolyte in an amount of about 4 mg/ml.

### Example 11E

The procedure of example 11 is followed except that the ZnPc-TTB is present in the redox electrolyte in an amount of about 5 mg/ml.

### Example 11F

The procedure of example 11 is followed except that the ZnPc-TTB is present in the redox electrolyte in an amount of about 6 mg/ml.

### Example 11G

The procedure of example 11 is followed except that the ZnPc-TTB is present in the redox electrolyte in an amount of about 8 mg/ml.

### Example 11H

The procedure of example 11 is followed except that the ZnPc-TTB is present in the redox electrolyte in an amount of about 10 mg/ml.

### Example 12

The procedure of example 11 is followed except that N-719 dye is substituted for Ru-505 dye.

### Example 12A

The procedure of example 12 is followed except that the ZnPc-TTB is present in the redox electrolyte in an amount of about 1.5 mg/ml.

### Example 12B

The procedure of example 12 is followed except that the ZnPc-TTB is present in the redox electrolyte in an amount of about 2.0 mg/ml.

### Example 12C

The procedure of example 12 is followed except that the ZnPc-TTB is present in the redox electrolyte in an amount of about 3 mg/ml.

### Example 12D

The procedure of example 12 is followed except that the ZnPc-TTB is present in the redox electrolyte in an amount of about 4 mg/ml.

### Example 12E

The procedure of example 12 is followed except that the ZnPc-TTB is present in the redox electrolyte in an amount of about 5 mg/ml.

### Example 12F

The procedure of example 12 is followed except that the ZnPc-TTB is present in the redox electrolyte in an amount of about 6 mg/ml.

### Example 12G

The procedure of example 12 is followed except that the ZnPc-TTB is present in the redox electrolyte in an amount of about 8 mg/ml.

### Example 12H

The procedure of example 12 is followed except that the ZnPc-TTB is present in the redox electrolyte in an amount of about 10 mg/ml.

### Example 13

The procedure of example 11 is followed except that Black dye is substituted for Ru-505 dye.

### Example 13A

The procedure of example 13 is followed except that the ZnPc-TTB is present in the redox electrolyte in an amount of about 1.5 mg/ml.

### Example 13B

The procedure of example 13 is followed except that the ZnPc-TTB is present in the redox electrolyte in an amount of about 2.0 mg/ml.

### Example 13C

The procedure of example 13 is followed except that the ZnPc-TTB is present in the redox electrolyte in an amount of about 3 mg/ml.

### Example 13D

The procedure of example 13 is followed except that the ZnPc-TTB is present in the redox electrolyte in an amount of about 4 mg/ml.

### Example 13E

The procedure of example 13 is followed except that the ZnPc-TTB is present in the redox electrolyte in an amount of about 5 mg/ml.

### Example 13F

The procedure of example 13 is followed except that the ZnPc-TTB is present in the redox electrolyte in an amount of about 6 mg/ml.

### Example 13G

The procedure of example 13 is followed except that the ZnPc-TTB is present in the redox electrolyte in an amount of about 8 mg/ml.

### Example 13H

The procedure of example 13 is followed except that the ZnPc-TTB is present in the redox electrolyte in an amount of about 10 mg/ml.

### Example 14

The method of example 11 is followed except that Nb₂O₅ coated wires as prepared in example 7 are substituted for the TiO₂ nanowires.

### Example 15

The method of example 12 is followed except that Nb₂O₅ coated wires as prepared in example 7 are substituted for the TiO₂ nanowires.

### Example 16

The method of example 13 is followed except that Nb₂O₅ coated wires as prepared in example 7 are substituted for the TiO₂ nanowires.

### Comparison Example 1

The procedure of example 11 is employed except that ZnPc-TTB is not present in the redox electrolyte.

### Comparison Example 2

The procedure of example 12 is employed except that ZnPc-TTB is not present in the redox electrolyte.

### Comparison Example 3

The procedure of example 13 is employed except that ZnPc-TTB is not present in the redox electrolyte

### Performance

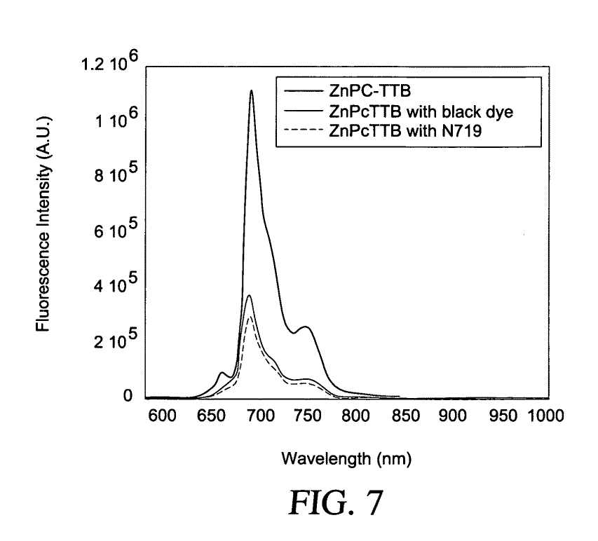

FIG. 7a shows emission spectra of a 25 microMolar solution of ZnPc-TTB in THF in the absence of exciton acceptor dyes and also when in the presence of exciton acceptor dyes such as N-719 and black dye.

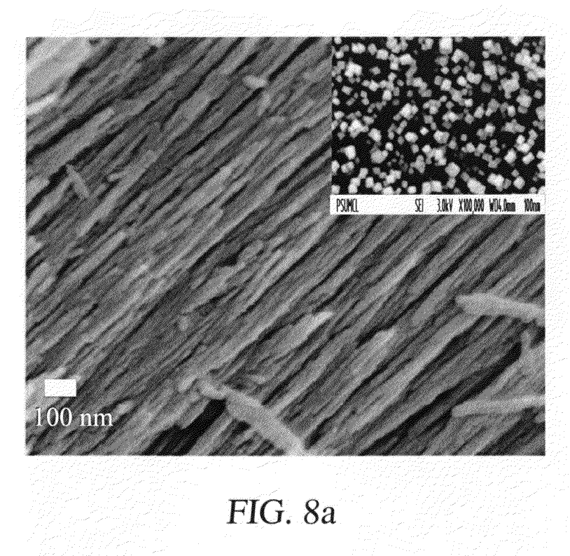

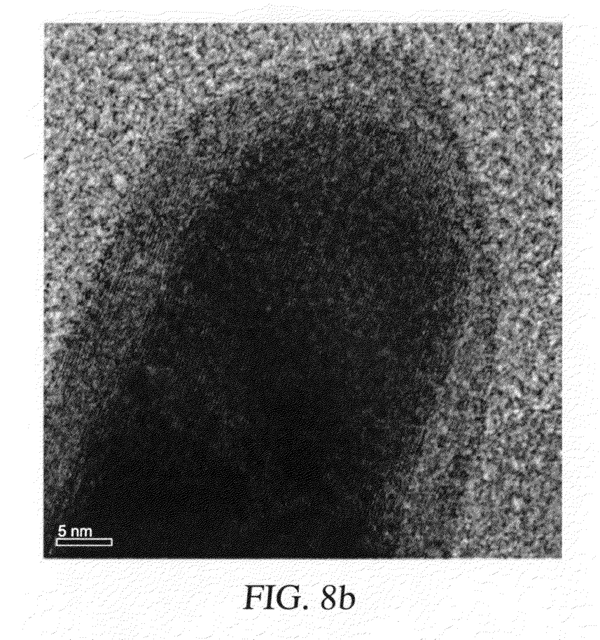

FIG. 8a shows field emission scanning electron microscope (FESEM) images of a single crystal rutile TiO₂ nanowire array, and FIG. 8b shows a high-resolution transmission electron microscope (HRTEM) image of a single crystal rutile TiO₂ nanowire.

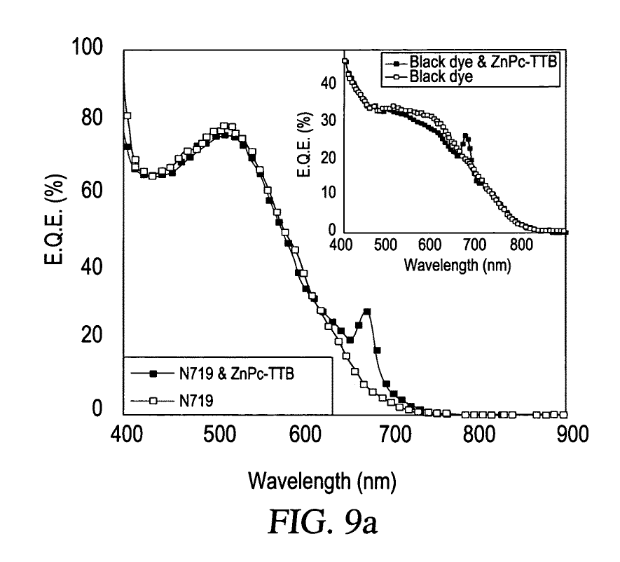

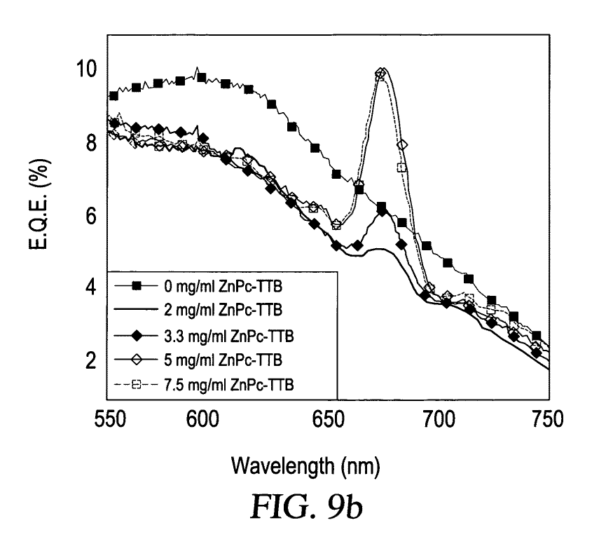

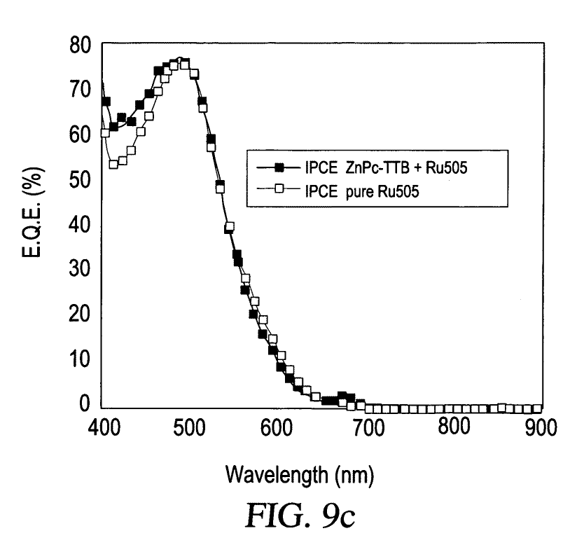

The solar cells shown in FIG. 9a employ TiO₂ rutile nanowires that are treated with electrolyte that includes ZnPc-TTB as in example 11. As shown in FIG. 9a, these cells achieve increased quantum yield for red photons in the spectral region of 670 nm to 690 nm above the quantum yields exhibited by N-719 and black-dye-sensitized nanowire solar cells.

As seen in FIG. 9a, a strong increase in the quantum yield for red photons in the spectral region of 670 nm to 690 nm occurs beyond the quantum yields shown by N-719 dye sensitized nanowire solar cells and by Black dye sensitized nanowire solar cells.

The effects of concentration of ZnPc-TTB in redox electrolyte are shown in FIG. 9b. As shown in FIG. 9b, increased ZnPc-TTB concentration in the electrolyte yields increased the quantum yields for red photons. Action spectra of the nanowire solar cells of example 13 that employ Ru-505-coated rutile as acceptors, with and without ZnPc-TTB molecules in electrolyte as donors, is shown in FIG. 9c.

Resonance energy transfer of excitons generated in ZnPc-TTB molecules from red photons to surface bound N-719 dye acceptor molecules on the TiO₂ nanowires results in a four-fold enhancement of quantum yield at about 675 nm to about 680 nm. This is shown in FIG. 9b.

1. A method of making semiconducting oxide nanowire arrays on a conducting oxide substrate comprising,
loading a conducting oxide substrate into a reactor in the presence of a reaction mixture of one or more non-polar solvents, one or more semi-conductor metal oxide precursor sources and one or more strong acids, and
heating the reactor to produce a nanowire array of a semiconducting oxide on the substrate wherein the semiconducting oxide is selected from the group consisting of TiO₂, WO₃, CuO, ZnO, SnO₂, V₂O₅, NiO, Nb₂O₅, Ta₂O₅ and mixtures thereof.

2. The method of claim 1 wherein the conducting oxide substrate is selected from the group consisting of SnO₂:In coated glass, SnO₂:In coated polyethylene, SnO₂:In coated polybutylene, SnO₂:In coated polyethyleneterephtalate, SnO₂:In coated copolymers of two or more of polyethylene, polybutylene, and polyethyleneterephtalate, SnO₂:F coated glass, SnO₂:F coated polyethylene, SnO₂:F coated polybutylene, SnO₂:F coated polyethyleneterephtalate, SnO₂:F coated copolymers of two or more of polyethylene, polybutylene and polyethyleneterephtalate and mixtures thereof.

3. A method of making rutile TiO₂ nanowire arrays on a conducting oxide substrate comprising,
loading a conducting oxide substrate into a sealed reactor in the presence of a reaction mixture of one or more non-polar solvents, one or more Ti⁴⁺ sources and one or more strong acids, and heating the reactor at about 1° C./min to about 30° C./min to a reaction temperature of about 150° C. to about 250° C. and holding at the reaction temperature for about 30 min to about 48 hours to produce a nanowire array of TiO₂ on the substrate.

4. The method of claim 3 wherein the conducting oxide substrate is selected from the group consisting of SnO₂:In coated glass substrates, SnO₂:In coated polyethylene, SnO₂:In coated polybutylene, SnO₂:In coated polyethyleneterephtalate, SnO₂:In coated copolymers of two or more of polyethylene, polybutylene, and polyethyleneterephtalate, SnO₂:F coated glass substrates, SnO₂:F coated polyethylene, SnO₂:F coated polybutylene, SnO₂:F coated polyethyleneterephtalate, SnO₂:F coated copolymers of two or more of polyethylene, polybutylene and polyethyleneterephtalate and mixtures thereof.

5. A method of making coated TiO₂ nanowire arrays comprising
immersing a SiO₂:F coated glass substrate into an aqueous Ti⁴⁺ precursor solution for about 2 to about 24 hours to yield a wetted substrate,
drying the wetted substrate at about 400° C. to about 500° C. for about 0.5 hrs to about 4 hrs to yield a TiO₂ coated substrate,
immersing the TiO₂ coated substrate into a reaction mixture that includes one or more nonpolar solvents, one or more Ti⁴⁺ sources and one or more strong acids,
heating the reaction mixture at about 1° C./min to about 30° C./min to a reaction temperature of about 150° C. to about 250° C.,
holding at the reaction temperature for about 30 min to about 48 hours to produce a TiO₂ nanowire array on the TiO₂ coated substrate,
immersing the TiO₂ coated substrate bearing the TiO₂ nanowires into a solution of a Group VB metal to produce wetted TiO₂ nanowires on the substrate, and
drying the wetted nanowires at about 400° C. to about 500° C. for about 0.5 hr to about 4 hrs to yield TiO₂ nanowires having a coating thereon on the substrate.

6. The method of claim 5 wherein the coating is Nb₂O₅.

7. A dye-sensitized solar cell comprising a rutile TiO₂ nanowire array made according to claim 5.

8. A method of manufacture of a dye sensitized, liquid Junction solar cell comprising,
treating a substrate bearing an array of dense packed semiconductor nanowires with a solution of an exciton acceptor dye to produce an array of exciton acceptor dye coated semiconductor nanowires,
infiltrating the array of acceptor dye coated semiconductor nanowires with a redox electrolyte that includes an electron donor dye,
attaching a counter-electrode to the array of coated semiconductor nanowires,
wherein the exciton acceptor dye and the exciton donor dye have a Forster radius there between, and
wherein spacings between the nanowires is about ±28% of the Forster radius.

9. The method of claim 8 wherein the semiconductor is rutile.

10. The method of claim 9 wherein the rutile is coated with Nb₂O₅.

11. The method of claim 9 wherein the nanowires are close packed.

12. The method of claim 9 wherein the exciton acceptor dye is ruthenium polypyridinium dye.

13. The method of claim 12 wherein the exciton donor dye is ZnPc-TTB.

14. A dye sensitized, liquid junction solar cell comprising,
a substrate bearing an array of dense packed exciton acceptor dye coated semiconductor nanowires,
a redox electrolyte that includes an electron donor dye interspersed between and in contact with the nanowires,
a counter-electrode attached to the array of coated semiconductor nanowires having an electron donor dye interspersed between and in contact with the nanowires,
the exciton acceptor dye and the exciton donor dye having a Forster radius there between, and
wherein spacings between the nanowires is about ±28% of the Forster radius between exciton acceptor dye and the exciton donor dye.

15. The cell of claim 14 wherein the semiconductor is rutile.

16. The cell of claim 15 wherein the rutile is coated with Nb₂O₅.

17. The cell of claim 15 wherein the nanowires are close packed.

18. The cell of claim 15 wherein the exciton acceptor dye is ruthenium polypyridinium dye.

19. The cell of claim 18 wherein the exciton donor dye is ZnPc-TTB.
